(19) United States
(12) Patent Application Publication
(10) Pub. No.: US 2016/0365538 A1
(43) Pub. Date: Dec. 15, 2016

(54) PACKAGING STRUCTURE OF OLED DEVICE AND PACKAGING METHOD THEREOF

(71) Applicant: Shenzhen China Star Optoelectronics Technology Co., Ltd., Shenzhen City (CN)

(72) Inventor: Jiajia Qian, Shenzhen City (CN)

(21) Appl. No.: 14/764,581

(22) PCT Filed: Jun. 29, 2015
(86) PCT No.: PCT/CN2015/082660

§ 371 Date: Jul. 30, 2015

(30) Foreign Application Priority Data
Jun. 15, 2015 (CN) 201510331335.6

(51) Int. Cl. H01L 51/52; H01L 51/56

(52) U.S. Cl. CPC H01L 51/5253; H01L 51/5259; H01L 51/56; H01L 2251/301; H01L 2251/303; H01L 2251/5338

(57) ABSTRACT

The present invention provides a packaging structure of an OLED device and a packaging method thereof. The packaging structure of the OLED device includes a substrate (1), an OLED device (2) arranged on the substrate (1), a first barrier layer (3) formed on the OLED device (2), a desiccant layer (4) formed on the first barrier layer (3), a buffer layer (5) formed on the desiccant layer (4), and a second barrier layer (6) formed on the buffer layer (5). The present invention uses the desiccant layer that is arranged in the packaging structure of the OLED device to improve the capability of the packaging structure for blocking moisture so as to effectively extend the lifespan of the OLED device. The packaging method of the OLED device according to the present invention effectively blocks the invasion of moisture, improve the effect of packaging, and effectively extend the lifespan of the OLED device. The method is simple and has good operability.

### BACKGROUND OF THE INVENTION

1. Field of the Invention

The present invention relates to the field of packaging technology, and in particular to a packaging structure of an organic light emitting diode (OLED) device and a packaging method thereof.

2. The Related Arts

OLED, which stands for organic light emitting diode, has various advantages, including self-luminous, high brightness, wide view angle, high contrast, being flexible, and low power consumption, and has attracted wide attention to serve as a new generation of displaying and gradually take the place of the conventional liquid crystal displays by being widely used in mobile phone screens, computer monitors, and full color televisions. The OLED display technology is different from the conventional liquid crystal display devices in that no backlighting is necessary and are made up of extremely thin coating layers of organic materials and glass substrates, wherein the organic materials give off light when electricity is applied thereto. However, these organic materials readily react with moisture or oxygen, as a display device based on the organic materials, an OLED display panel requires severe standards of packaging.

Most of the organic materials of an OLED emissive layer are very sensitive to contaminants, oxygen, and moisture contained in the atmosphere. Electrochemical corrosions occur readily in a moisture-rich environment, severely affecting the lifespan of the OLED device. Thus, it is of vital importance for stable emission of light of an OLED device that the OLED device is well packaged to improve leak-tightness of the interior of the device for isolation from the external surroundings to the most extent.

A conventional way of packaging of an OLED device is achieved by applying packaging resin on a rigid package substrate (such as glass or metal). Such a process is not applicable to a flexible device. A technique that uses laminated films to package an OLED device has been proposed. The laminated film based packaging is to form two barrier layers that are made of inorganic materials having excellent property of water resistance on an OLED device that is formed on a substrate and a buffer layer that is made of an organic material having excellent flexibility between the two barrier layers. Specifically, referring to FIG. 1, such an OLED device packaging structure comprises a substrate 10, an OLED device 20 formed on the substrate 10, a first barrier layer 30 formed on the OLED device 20, a buffer layer 40 formed on the first barrier layer 30, and a second barrier layer 50 formed on the buffer layer 40. Such an OLED device packaging structure heavily relies on the quality of each of the layers, especially the quality of the inorganic layer. As shown in FIG. 2, the inorganic layer is formed in a low temperature and may inevitably comprise defects existing therein to provide passages for invasion of moisture. This causes deterioration of the performance of the packaging structure.

### SUMMARY OF THE INVENTION

An object of the present invention is to provide a packaging structure of an organic light emitting diode (OLED) device, which shows an excellent effect of blocking moisture and provides an excellent effect of packaging and is suitable for flexible OLED displays.

Another object of the present invention is to provide an OLED packaging method, which has a simple process, is easy to operate, provides an excellent effect of packaging, shows an excellent effect of blocking moisture, and is suitable for flexible OLED displays.

To achieve the above objects, the present invention provides a packaging structure of an OLED device, which comprises a substrate, an OLED device arranged on the substrate, a first barrier layer formed on the OLED device, a desiccant layer formed on the first barrier layer, a buffer layer formed on the desiccant layer, and a second barrier layer formed on the buffer layer.

The first barrier layer and the second barrier layer each comprise an inorganic film of SiNx or Al₂O₃; and the buffer layer comprises an organic film.

The first barrier layer completely covers the OLED device; and the desiccant layer is set above and completely shields, in a vertical direction, the OLED device.

The buffer layer is set above and completely shields, in a vertical direction, the OLED device; and the second barrier layer completely covers the first barrier layer, the desiccant layer, and the buffer layer.

The substrate comprises a flexible substrate.

The present invention also provides a packaging structure of an OLED device, which comprises a substrate, an OLED device arranged on the substrate, a first barrier layer formed on the OLED device, a desiccant layer formed on the first barrier layer, a buffer layer formed on the desiccant layer, and a second barrier layer formed on the buffer layer;

wherein the first barrier layer and the second barrier layer each comprise an inorganic film of SiNx or Al₂O₃; and the buffer layer comprises an organic film;

wherein the first barrier layer completely covers the OLED device; and the desiccant layer is set above and completely shields, in a vertical direction, the OLED device; and

wherein the buffer layer is set above and completely shields, in a vertical direction, the OLED device; and the second barrier layer completely covers the first barrier layer, the desiccant layer, and the buffer layer.

The present invention also provides a packaging method of an OLED device, which comprises the following steps:

(1) providing a substrate and forming, through vapor deposition, an OLED device on the substrate;

(2) forming a first barrier layer on the OLED device;

(3) forming a desiccant layer on the first barrier layer;

(4) forming a buffer layer on the desiccant layer; and

(5) forming a second barrier layer on the buffer layer.

The first barrier layer formed in Step (2) and the second barrier layer formed in Step (5) each comprise an inorganic film of SiNx or Al₂O₃; and the first barrier layer formed in Step (2) and the second barrier layer formed in Step (5) are formed through plasma enhanced chemical vapor deposition or atomic layer deposition; and the buffer layer formed in Step (4) comprises an organic film.

Step (3) comprises coating and curing a desiccant, through printing, on the first barrier layer to form the desiccant layer.

The first barrier layer completely covers the OLED device; the desiccant layer and the buffer layer are respectively set above and completely shield, in a vertical direction, the OLED device; and the second barrier layer completely covers the first barrier layer, the desiccant layer, and the buffer layer.

The substrate provided in Step (1) comprises a flexible substrate.

The efficacy of the present invention is that the present invention provides a packaging structure of an OLED device, which comprises a desiccant layer that is arranged between the first barrier layer and the buffer layer and completely shields, in the vertical direction, the OLED device so that moisture that invades into the interior of the packaging structure is absorbed by the desiccant to cut off the invasion passage of the moisture and thus improve the capability of the packaging structure for blocking moisture and effectively extend the lifespan of the OLED device. The present invention provides a packaging method of an OLED device, which comprises arranging a desiccant layer between the first barrier layer and the buffer layer to completely shield, in the vertical direction, the OLED device so that moisture that invades into the interior of the packaging structure is absorbed by the desiccant to cut off the invasion passage of the moisture and thus improve the capability of the packaging structure for blocking moisture and effectively extend the lifespan of the OLED device. Further, the method is simple and has good operability.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIG. 1 is a cross-sectional view showing a conventional packaging structure of an organic light emitting diode (OLED) device;

FIG. 2 is a schematic view illustrating invasion of moisture through defects of barrier layers of the conventional packaging structure of the OLED device shown in FIG. 1;

FIG. 3 is a cross-sectional view showing a packaging structure of an OLED device according to the present invention;

FIG. 4 is a schematic view illustrating invasion of moisture through defects formed in a barrier layer of the packaging structure of the OLED device shown in FIG. 3;

FIG. 5 is a flow chart illustrating a packaging method of an OLED device according to the present invention;

FIG. 6 is a schematic view illustrating a first step of the packaging method of the OLED device according to the present invention;

FIG. 7 is a schematic view illustrating a second step of the packaging method of the OLED device according to the present invention;

FIG. 8 is a schematic view illustrating a third step of the packaging method of the OLED device according to the present invention; and

FIG. 9 is a schematic view illustrating a fourth step of the packaging method of the OLED device according to the present invention.

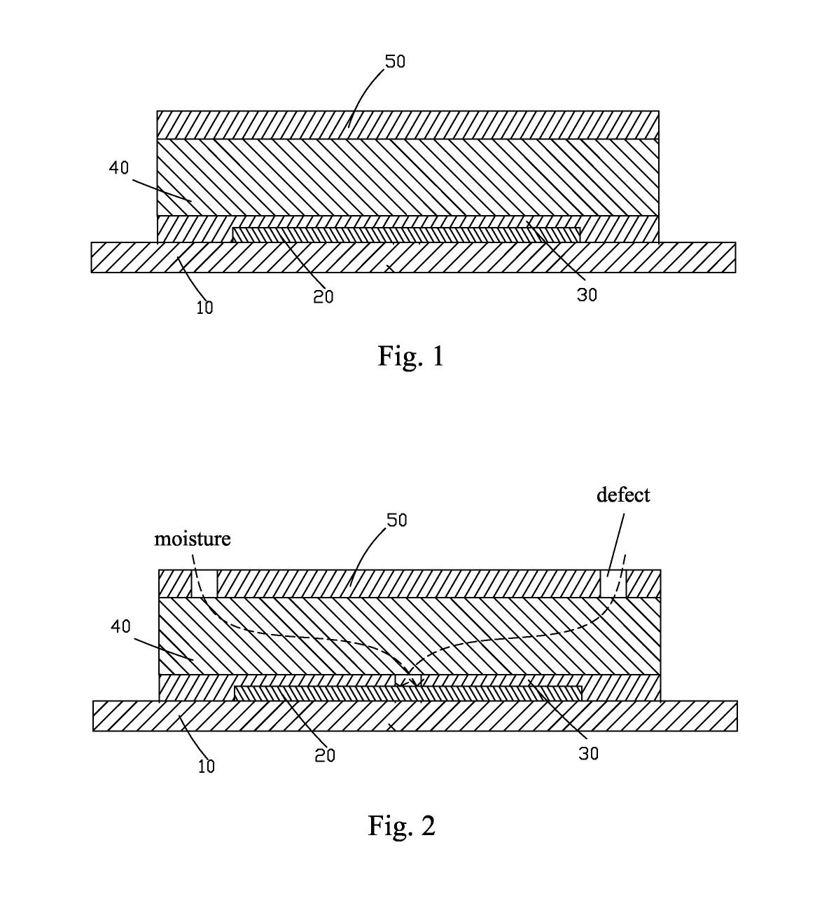

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

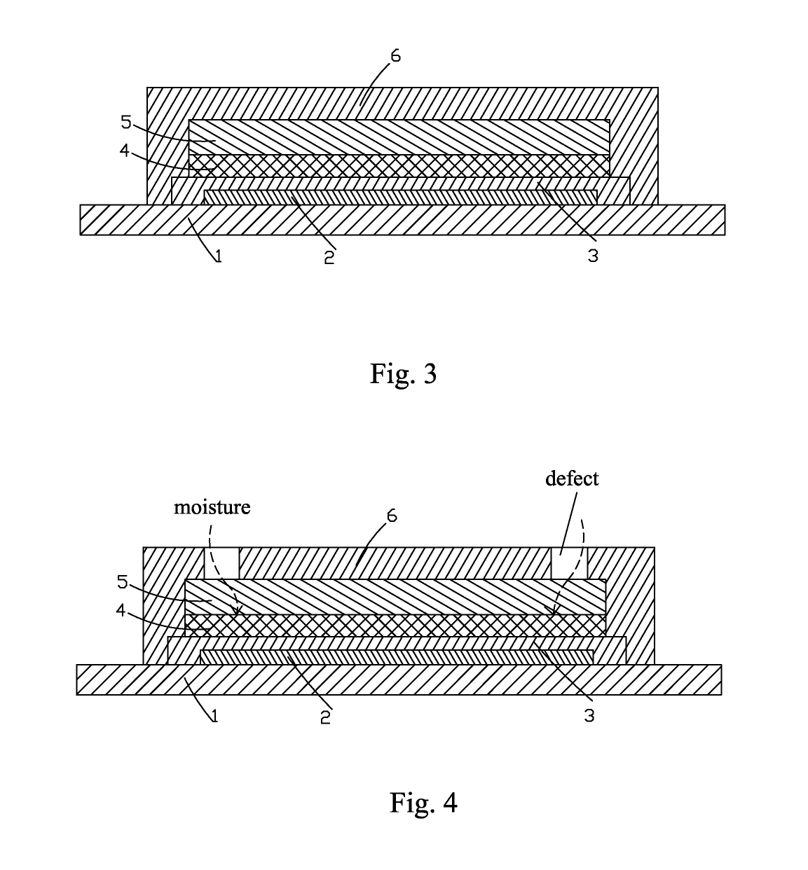

Referring to FIG. 3, the present invention provides a packaging structure of an organic light emitting diode (OLED) device, which comprises a substrate 1, an OLED device 2 arranged on the substrate 1, a first barrier layer 3 formed on the OLED device 2, a desiccant layer 4 formed on the first barrier layer 3, a buffer layer 5 formed on the desiccant layer 4, and a second barrier layer 6 formed on the buffer layer 5.

Specifically, the first barrier layer 3 and the second barrier layer 6 each comprise a SiNx or Al₂O₃ inorganic film; and the buffer layer 5 comprises an organic film.

Specifically, the first barrier layer 3 completely covers the OLED device 2; the desiccant layer 4 and the buffer layer 5 are arranged to set above and completely shield, in a vertical direction, the OLED device 2; and the second barrier layer 6 completely cover the first barrier layer 3, the desiccant layer 4, and the buffer layer 5.

Specifically, the substrate 1 is a flexible substrate.

Referring to FIG. 4, in the packaging structure of the OLED device according to the present invention, when the first barrier layer 3 or the second barrier layer 5 comprises defects formed therein, moisture that penetrates through the buffer layer 5 and enters the interior of the packaging structure can be absorbed by the desiccant layer 4, cutting off the invasion passage of the moisture, thereby effectively extending the lifespan of the OLED device.

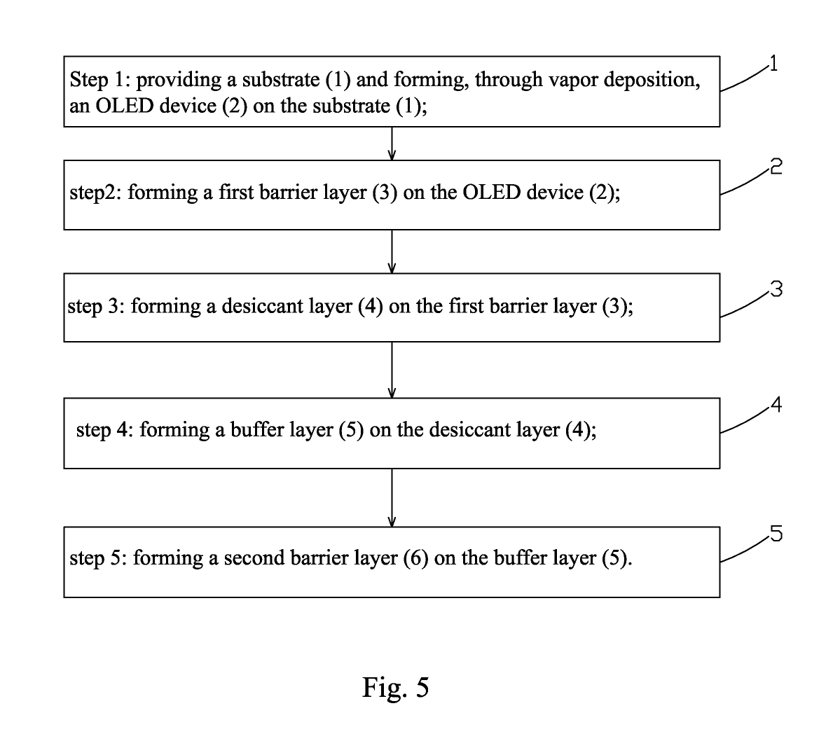

As shown in FIG. 5, the present invention also provides a packaging method of an OLED device, which comprises the following steps:

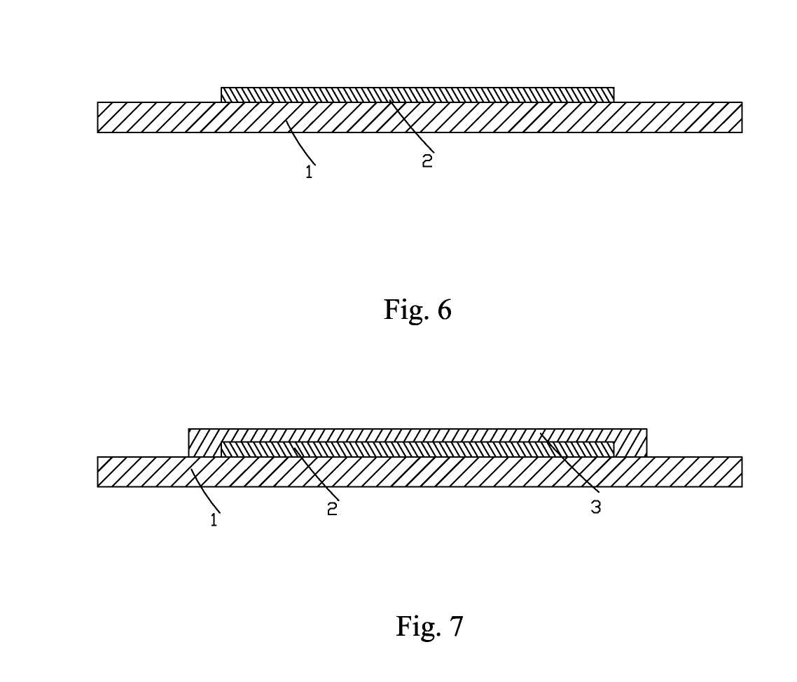

Step 1: as shown in FIG. 6, providing a flexible substrate 1 and forming, through vapor deposition, an OLED device 2 on the flexible substrate 1;

Step 2: as shown in FIG. 7, forming a first barrier layer 3 on the OLED device 2;

wherein, specifically, the first barrier layer 3 completely covers the OLED device 2; the first barrier layer 3 comprises a SiNx or Al₂O₃ inorganic film, the first barrier layer 3 being formed through plasma enhanced chemical vapor deposition (PECVD) or atomic layer deposition (ALD); and

wherein, specifically, the first barrier layer 3 formed in Step 2 has a surface area that is greater than a surface area of the OLED device 2 and the first barrier layer 3 completely covers the OLED device 2;

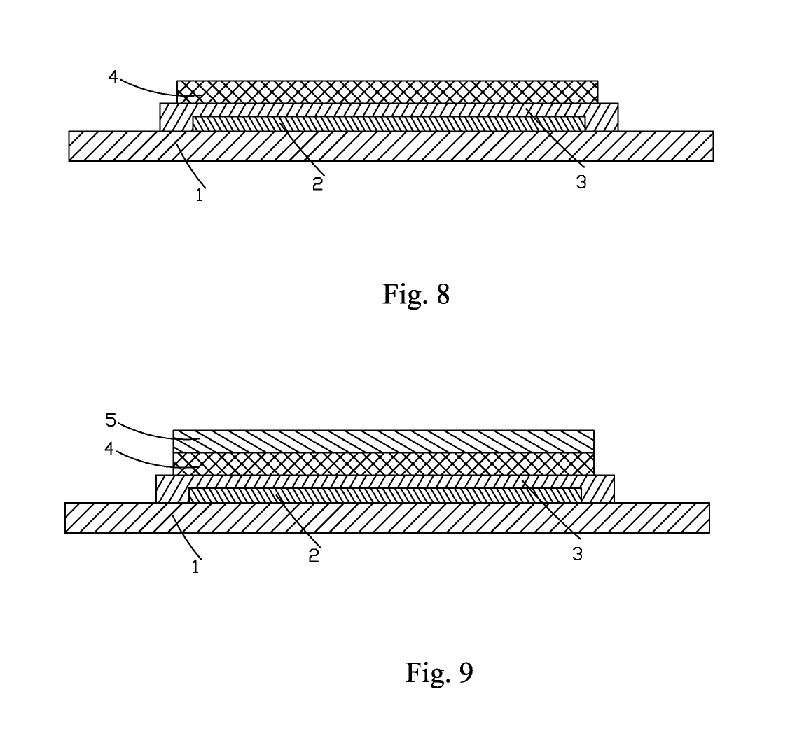

Step 3: as shown in FIG. 8, forming a desiccant layer 4 on the first barrier layer 3;

wherein, specifically, a desiccant is coated, through printing, on the first barrier layer 3 and cured to form the desiccant layer 4;

wherein, specifically, the desiccant layer 4 formed in Step 3 has a surface area that is greater than the surface area of the OLED device 2 and the desiccant layer 4 is set above and completely shields, in the vertical direction, the OLED device 2;

Step 4: as shown in FIG. 9, forming a buffer layer 5 on the desiccant layer 4;

wherein, specifically, the buffer layer 5 comprises an organic film and the buffer layer 5 formed in Step 4 has a surface area that is greater than the surface area of the OLED device 2 and the buffer layer 5 is set above and completely shields, in the vertical direction, the OLED device 2;

Step 5: forming a second barrier layer 6 on the buffer layer 5 to form the OLED device packaging structure as shown in FIG. 3 thereby completing the packaging of the OLED device.

Specifically, the second barrier layer 6 comprises a SiNx or Al₂O₃ inorganic film and the second barrier layer 6 is formed through PECVD or ALD.

Specifically, the second barrier layer 6 has a surface area that is greater than the surface areas of the desiccant layer 4 and the buffer layer 5 and thus, the second barrier layer 6 completely covers the first barrier layer 3, the desiccant layer 4, and the buffer layer 5.

In summary, the present invention provides a packaging structure of an OLED device, which comprises a desiccant layer that is arranged between the first barrier layer and the buffer layer and completely shields, in the vertical direction, the OLED device so that moisture that invades into the interior of the packaging structure is absorbed by the desiccant to cut off the invasion passage of the moisture and thus improve the capability of the packaging structure for blocking moisture and effectively extend the lifespan of the OLED device. The present invention provides a packaging method of an OLED device, which comprises arranging a desiccant layer between the first barrier layer and the buffer layer to completely shield, in the vertical direction, the OLED device so that moisture that invades into the interior of the packaging structure is absorbed by the desiccant to cut off the invasion passage of the moisture and thus improve the capability of the packaging structure for blocking moisture and effectively extend the lifespan of the OLED device. Further, the method is simple and has good operability.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A packaging structure of an organic light emitting diode (OLED) device, comprising a substrate, an OLED device arranged on the substrate, a first barrier layer formed on the OLED device, a desiccant layer formed on the first barrier layer, a buffer layer formed on the desiccant layer, and a second barrier layer formed on the buffer layer.

2. The packaging structure of the OLED device as claimed in claim 1, wherein the first barrier layer and the second barrier layer each comprise an inorganic film of SiNx or Al₂O₃; and the buffer layer comprises an organic film.

3. The packaging structure of the OLED device as claimed in claim 1, wherein the first barrier layer completely covers the OLED device; and the desiccant layer is set above and completely shields, in a vertical direction, the OLED device.

4. The packaging structure of the OLED device as claimed in claim 1, wherein the buffer layer is set above and completely shields, in a vertical direction, the OLED device; and the second barrier layer completely covers the first barrier layer, the desiccant layer, and the buffer layer.

5. The packaging structure of the OLED device as claimed in claim 1, wherein the substrate comprises a flexible substrate.

6. A packaging structure of an organic light emitting diode (OLED) device, comprising a substrate, an OLED device arranged on the substrate, a first barrier layer formed on the OLED device, a desiccant layer formed on the first barrier layer, a buffer layer formed on the desiccant layer, and a second barrier layer formed on the buffer layer;
wherein the first barrier layer and the second barrier layer each comprise an inorganic film of SiNx or Al₂O₃; and the buffer layer comprises an organic film;
wherein the first barrier layer completely covers the OLED device; and the desiccant layer is set above and completely shields, in a vertical direction, the OLED device; and
wherein the buffer layer is set above and completely shields, in a vertical direction, the OLED device; and the second barrier layer completely covers the first barrier layer, the desiccant layer, and the buffer layer.

7. The packaging structure of the OLED device as claimed in claim 6, wherein the substrate comprises a flexible substrate.

8. A packaging method of an organic light emitting diode (OLED) device, comprising the following steps:
(1) providing a substrate and forming, through vapor deposition, an OLED device on the substrate;
(2) forming a first barrier layer on the OLED device;
(3) forming a desiccant layer on the first barrier layer;
(4) forming a buffer layer on the desiccant layer; and
(5) forming a second barrier layer on the buffer layer.

9. The packaging method of the OLED device as claimed in claim 8, wherein the first barrier layer formed in Step (2) and the second barrier layer formed in Step (5) each comprise an inorganic film of SiNx or Al₂O₃; and
the first barrier layer formed in Step (2) and the second barrier layer formed in Step (5) are formed through plasma enhanced chemical vapor deposition or atomic layer deposition; and the buffer layer formed in Step (4) comprises an organic film.

10. The packaging method of the OLED device as claimed in claim 8, wherein Step (3) comprises coating and curing a desiccant, through printing, on the first barrier layer to form the desiccant layer.

11. The packaging method of the OLED device as claimed in claim 8, wherein the first barrier layer completely covers the OLED device; the desiccant layer and the buffer layer are respectively set above and completely shield, in a vertical direction, the OLED device; and the second barrier layer completely covers the first barrier layer, the desiccant layer, and the buffer layer.

12. The packaging method of the OLED device as claimed in claim 8, wherein the substrate provided in Step (1) comprises a flexible substrate.
